(19) United States
(12) Patent Application Publication
(10) Pub. No.: US 2025/0273368 A1
(43) Pub. Date: Aug. 28, 2025

(54) ELECTRONIC COMPONENT AND ELECTRONIC APPARATUS

(71) Applicant: Tokyo Cosmos Electric Co., Ltd., Zama-shi, Kanagawa (JP)

(72) Inventor: Hajime FUKUSHIMA, Zama-shi, Kanagawa (JP)

(73) Assignee: Tokyo Cosmos Electric Co., Ltd., Zama-shi,Kanagawa (JP)

(21) Appl. No.: 18/858,356

(22) PCT Filed: Mar. 23, 2023
(86) PCT No.: PCT/JP2023/011556

§ 371 Date: Oct. 21, 2024

(30) Foreign Application Priority Data
Apr. 25, 2022 (JP) 2022-071790

(51) Int. Cl. H01C 1/02; H01C 1/144; H01C 10/32

(52) U.S. Cl. CPC H01C 1/02; H01C 1/144; H01C 10/32

(57) ABSTRACT

This electronic component and electronic apparatus enable the rotational torque to be sufficiently increased, enhance the waterproofing performance, and enable easy soldering of a terminal onto a circuit board. The electronic component comprises: an electronic component body that is disposed inside a case and that is installed on the surface of a circuit board facing the inside of the case; an input shaft that passes through a cylindrical section that follows the surface from the electronic component body and is provided to the case, the input axis extending to the outside of the case; and a fitting member that fits into the gap between the cylindrical section and the input shaft. For example, the fitting member is provided with a ring-shaped section that includes: an inner edge in contact with the input shaft; and an outer edge in contact with the cylindrical section.

### TECHNICAL FIELD

The present invention relates to an electronic component and an electronic apparatus.

### BACKGROUND ART

Rotation-type electronic components such as a potentiometer that outputs a voltage corresponding to the mechanical displacement amount of the rotation of an input shaft and a rotary encoder that converts the mechanical displacement amount of the rotation of the input shaft into a digital amount are known.

As a conventional rotation-type electronic component, for example, Patent Literature 1 describes a rotation-type electronic component including an electronic component main body, an input shaft that extends from the inside to the outside of the electronic component main body, an electrode pattern that is disposed inside the electronic component main body, a slider that is rotatably supported inside the electronic component main body, rotates integrally with the input shaft, and slides on the electrode pattern, and a terminal that extends from the electrode pattern to the outside of the electronic component main body and is connected to a circuit board.

### CITATION LIST

### Patent Literature

### PTL1

Japanese Patent Application Laid-Open No. 2005-347522

### SUMMARY OF INVENTION

### Technical Problem

By the way, since a rotation-type electronic component is required to be reduced in size and is constrained by a structure for generating a rotation torque, it is not possible to sufficiently increase the rotation torque. In addition, since the input shaft rotates, it is difficult to adopt a waterproof structure through which water is prevented from entering the electronic apparatus, and it is difficult to enhance the waterproof property.

Further, in the work of soldering the terminal to the circuit board, since the center of gravity of the input shaft is located in the upward direction of the lower surface of the electronic component main body loaded on the circuit board in the electronic component described in Patent Literature 1, the terminal can be easily soldered to the circuit board in a state in which the electronic component main body is stabilized on the circuit board. However, in a case where the center of gravity of the input shaft is not located in the upward direction of the lower surface of the electronic component main body, for example, in a case where input shaft 218 extends from electronic component main body 212 in a horizontal direction, as illustrated in electronic apparatus 200 of FIG. 1A, electronic component main body 212 is inclined toward a side of input shaft 218 with respect to circuit board 203, as illustrated in FIG. 1B. That is, it is difficult to solder terminal 217 to circuit board 203 in a state in which electronic component main body 212 is stabilized on circuit board 203.

An object of the present invention is to provide an electronic component and an electronic apparatus each capable of sufficiently increasing a rotation torque, enhancing waterproof property, and easily soldering a terminal to a circuit board.

### Solution to Problem

To achieve the above-described object, an electronic component according to the present invention includes: an electronic component main body disposed in an inside of a case and mounted on a surface in a circuit board, the surface facing the inside of the case; an input shaft that that extends to an outside of the case from the electric component main body along the surface and through a cylindrical portion provided in the case; and a fitting member that fits to a gap between the cylindrical portion and the input shaft.

An electronic apparatus according to the present invention includes: the above-described electronic component; the above-described case; and the above-described circuit board.

### Advantageous Effects of Invention

According to the present invention, it is possible to sufficiently increase a rotation torque, to enhance the waterproof property, and to easily solder a terminal to the circuit board.

### BRIEF DESCRIPTION OF DRAWINGS

FIG. 1A illustrates a method of assembling an electronic apparatus according to a comparative example;

FIG. 1B illustrates an electronic component that is inclined with respect to a circuit board;

FIG. 2 illustrates an electronic apparatus in an embodiment of the present invention;

FIG. 3 illustrates an exemplary method of assembling an electronic apparatus in the embodiment of the present invention;

FIG. 4 illustrates an electronic apparatus in Variation 1;

FIG. 5 illustrates an electronic apparatus in Variation 2; and

FIG. 6 illustrates an electronic apparatus in Variation 3.

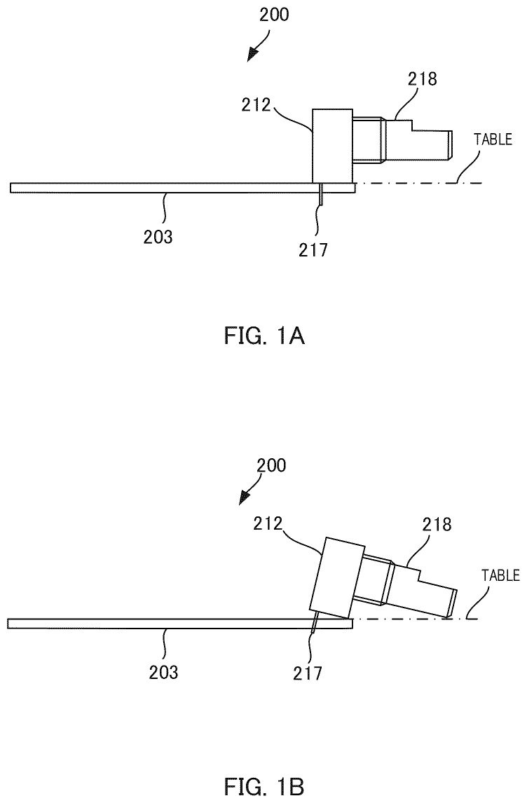

### DESCRIPTION OF EMBODIMENTS

Hereinafter, an embodiment of the present invention will be described with reference to the drawings.

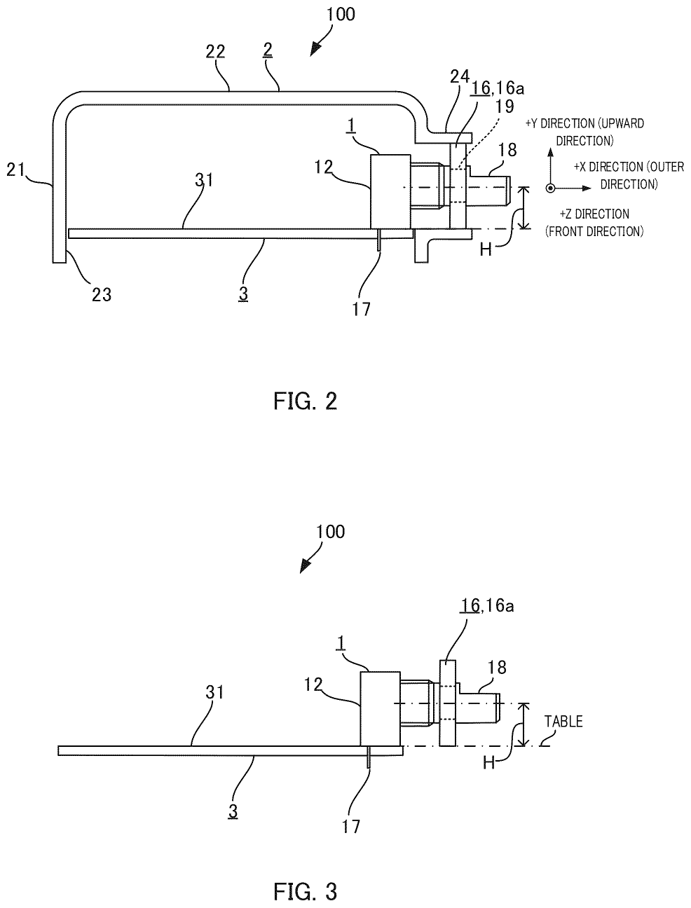

FIG. 2 illustrates an electronic apparatus in the embodiment of the present invention. FIG. 2 illustrates an X-axis, a Y-axis, and a Z-axis. In FIG. 2, a right-left direction is referred to as the axial direction or the X direction, a right direction is referred to as one side in the axial direction or a “+X direction,” and a left direction is referred to as the other side in the axial direction or a “−X direction.” Moreover, in FIG. 2, an up-down direction is referred to as the Y direction, an upward direction is referred to as a “+Y direction,” and a downward direction as a “−Y direction.” Further, a direction orthogonal to the plane in FIG. 2 is referred to as a depth direction or the Z direction, a front direction is referred to as a front side or a “+Z direction,” and a rear direction is referred to as a rear side or a “−Z direction.”

Electronic apparatus 100 in the present embodiment includes electronic component 1, case 2, and circuit board 3. In the present embodiment, electronic component 1 is a potentiometer that outputs a voltage corresponding to the mechanical displacement amount of the rotation of an input shaft, or a rotary encoder that converts the mechanical displacement amount of the rotation of the input shaft into a digital amount.

As illustrated in FIG. 2, electronic component 1 includes electronic component main body 12, fitting member 16, terminal 17, and input shaft 18. A shaft bearing (not illustrated), a slider (not illustrated), and a resistance board (not illustrated) are provided inside electronic component main body 12.

Case 2 includes peripheral wall 21 and ceiling wall 22. Case 2 includes opening portion 23 that is open in the downward direction (−Y direction). Cylindrical portion 24 is disposed on peripheral wall 21. Cylindrical portion 24 communicates between the inside and the outside of case 2 in the axial direction (X direction). Cylindrical portion 24 has a circular shape when viewed from the X direction indicated by the arrow.

Circuit board 3 is disposed to close opening portion 23 from the downward direction (−Y direction). Surface 31 of circuit board 3 faces the inside of case 2. Electronic component main body 12 is mounted on surface 31 of circuit board 3.

Input shaft 18 is a shaft having a circular cross-sectional shape with a predetermined outer diameter. Input shaft 18 extends from electronic component main body 12 along surface 31 and through cylindrical portion 24, to the outside of case 2. Input shaft 18 passes through a central position (position at distance H from surface 31 illustrated in FIG. 2) of cylindrical portion 24 having a circular shape. Accordingly, a gap having an annular shape is formed between cylindrical portion 24 and input shaft 18. An end of input shaft 18 on the other side in the axial direction (−X direction) is rotatably supported by the shaft bearing provided in electronic component main body 12. The slider rotates integrally with input shaft 18 and slides on an electrode pattern disposed on the resistance board. Note that the other side in the axial direction (−X direction) of input shaft 18 corresponds to an “inner side of the case” of the present invention.

Fitting member 16 fits to the gap between cylindrical portion 24 and input shaft 18. Fitting member 16 includes annular portion 16a having an inner peripheral edge that is in contact with an outer periphery of input shaft 18 and an outer peripheral edge that is in contact with an inner periphery of cylindrical portion 24. Fitting member 16 is an elastic rubber ring.

Since a frictional force generated between annular portion 16a and input shaft 18 increases in accordance with an area and force when the inner peripheral edge of annular portion 16a comes into contact with the outer periphery of input shaft 18, a rotation torque of input shaft 18 increases. Further, since a frictional force generated between annular portion 16a and cylindrical portion 24 increases in accordance with an area and force when the outer peripheral edge of annular portion 16a comes into contact with the inner periphery of cylindrical portion 24, the rotation of annular portion 16a with respect to cylindrical portion 24 can be prevented. Note that the structure for preventing the rotation of annular portion 16a with respect to cylindrical portion 24 is not limited to this.

In the above embodiment, cylindrical portion 24 has a circular shape when viewed from the X direction indicated by the arrow, but an inner peripheral shape of cylindrical portion 24 and the like may be a polygonal shape (for example, rectangular shape or hexagonal shape). For example, the inner peripheral shape of cylindrical portion 24 may be a rectangular shape including an upper side surface and a lower side surface that face each other in the up-down direction (Y direction), and a front side surface and a rear side surface that face each other in the depth direction (Z direction). Further, in this case, an outer peripheral shape of annular portion 16a may be a polygonal shape that corresponds to the inner peripheral shape of cylindrical portion 24. Thus, since sides of the inner periphery of cylindrical portion 24 and the outer periphery of annular portion 16a come into contact with each other, the rotation of annular portion 16a with respect to cylindrical portion 24 can be prevented.

As above, when the inner periphery of annular portion 16a is in contact with the outer periphery of input shaft 18 and the outer periphery of annular portion 16a is in contact with the inner periphery of cylindrical portion 24, it is possible to increase the rotation torque of input shaft 18 while preventing the rotation of annular portion 16a with respect to cylindrical portion 24. Note that a material for annular portion 16a may be selected from publicly known materials to prevent the rotation of annular portion 16a and to be suitable for increasing the rotation torque of input shaft 18.

In addition, in a structure in which the inner periphery of annular portion 16a is in contact with the outer periphery of input shaft 18 and the outer periphery of annular portion 16a is in contact with the inner periphery of cylindrical portion 24, since the gap between input shaft 18 and cylindrical portion 24 is blocked by annular portion 16a from the one side in the axial direction (+X direction), no water enters the inside of electronic component main body 12 through the gap from the one side in the axial direction (+X direction). Thus, it is possible to enhance the waterproof property. Note that the one side in the axial direction (+X direction) of input shaft 18 corresponds to an “outer side of the case” of the present invention.

Input shaft 18 includes stopper portion (or retainer portion; hereinafter referred to as stopper) 19 that prevents fitting member 16 from coming off. An outer diameter of stopper 19 in input shaft 18 is smaller than an outer diameter of a portion of stopper 19 on one side in the axial direction (+X direction), and is smaller than an outer diameter of a portion of stopper 19 on the other side in the axial direction (−X direction). The inner periphery of annular portion 16a is in contact with stopper 19. This prevents fitting member 16 from coming off from input shaft 18.

Even in a case where input shaft 18 extends along surface 31 of circuit board 3 in the axial direction (X direction) from electronic component main body 12, electronic component main body 12 is not inclined with respect to circuit board 3 because input shaft 18 is supported by fitting member 16. Thus, since electronic component main body 12 can be stabilized on circuit board 3, it is possible to solder terminal 17 to circuit board 3 easily.

Next, an exemplary method of assembling electronic apparatus 100 will be described.

First, fitting member 16 externally fits to input shaft 18 of electronic component 1.

Next, electronic component 1 is mounted on circuit board 3. At this time, since input shaft 18 is supported by fitting member 16, electronic component 1 is not inclined toward a side of input shaft 18 with respect to circuit board 3. A radius of annular portion 16a illustrated in FIG. 3 is equal to distance H from a position of a table (position of surface 31 of circuit board 3) to a central position of input shaft 18. Thus, since the outer peripheral edge of annular portion 16a comes into contact with the table, input shaft 18 is supported by fitting member 16.

Next, terminal 17 is soldered to circuit board 3. Since electronic component 1 is not inclined toward a side of input shaft 18 with respect to circuit board 3, terminal 17 can be easily soldered to circuit board 3 in a state in which electronic component 1 is stabilized on circuit board 3.

Next, after positioning case 2 and circuit board 3 with respect to each other while making an internal fitting of fitting member 16 to cylindrical portion 24 of case 2, the components are assembled using the fastening tool.

Electronic component 1 according to the above embodiment includes: electronic component main body 12 that is disposed inside of case 2 and mounted on surface 31 facing the inside of case 2 of circuit board 3; input shaft 18 that is rotatably supported by electronic component main body 12, and that extends to the outside of case 2 from electronic component main body 12 along surface 31 and through cylindrical portion 24 provided in case 2; and fitting member 16 that fits to a gap between cylindrical portion 24 and input shaft 18.

With the above configuration, since fitting member 16 fits to the gap between cylindrical portion 24 and input shaft 18, a rotation torque of input shaft 18 can be generated with a frictional force generated between fitting member 16 and input shaft 18. Further, it is possible to sufficiently increase the rotation torque by appropriately setting the shape, the thickness, the material, and the like of fitting member 16. Further, when fitting member 16 externally fits to input shaft 18 and internally fits to cylindrical portion 24, since the gap between input shaft 18 and cylindrical portion 24 is blocked from the one side in the axial direction (+X direction) by annular portion 16a, it is possible to enhance the waterproof property. Further, when fitting member 16 supports terminal 17, since electronic component main body 12 is not inclined toward a side of input shaft 18 with respect to circuit board 3, it is possible to solder terminal 17 to circuit board 3 easily.

Further, in the above embodiment, fitting member 16 includes annular portion 16a having an inner peripheral edge that is in contact with the outer periphery of input shaft 18 and an outer peripheral edge that is in contact with the inner periphery of cylindrical portion 24. Further, annular portion 16a is an elastic rubber ring. Thus, it is possible to adjust the rotation torque and to enhance the waterproof property by appropriately setting an extent to which the inner peripheral edge of annular portion 16a is in contact with the outer periphery of input shaft 18 and/or an extent to which the outer peripheral edge of annular portion 16a is in contact with the inner periphery of cylindrical portion 24.

Further, in the above embodiment, input shaft 18 includes stopper 19 that prevents fitting member 16 from coming off. Further, since stopper 19 serves as a mark for external fitting of fitting member 16 to the position of stopper 19, and since an operator can recognize that fitting member 16 has fitted to stopper 19, it is possible to increase the assemblability. Furthermore, since fitting member 16 is made difficult to come off from input shaft 18 during transportation, it is possible to increase the transportability.

Further, in the above embodiment, the radius of annular portion 16a is equal to the distance from the position of surface 31 of circuit board 3 to the central position of input shaft 18. Thus, since annular portion 16a supports input shaft 18, it is possible to prevent electronic component main body 12 from inclining toward a side of input shaft 18 with respect to circuit board 3. Thus, since electronic component main body 12 can be stabilized on surface 31 of circuit board 3, terminal 17 can be easily soldered to circuit board 3. Note that, in a case where circuit board 3 does not extend to a position below input shaft 18, the table may be installed instead of circuit board 3 at a position identical to the position of surface 31, as illustrated in FIG. 3.

### (Variation 1)

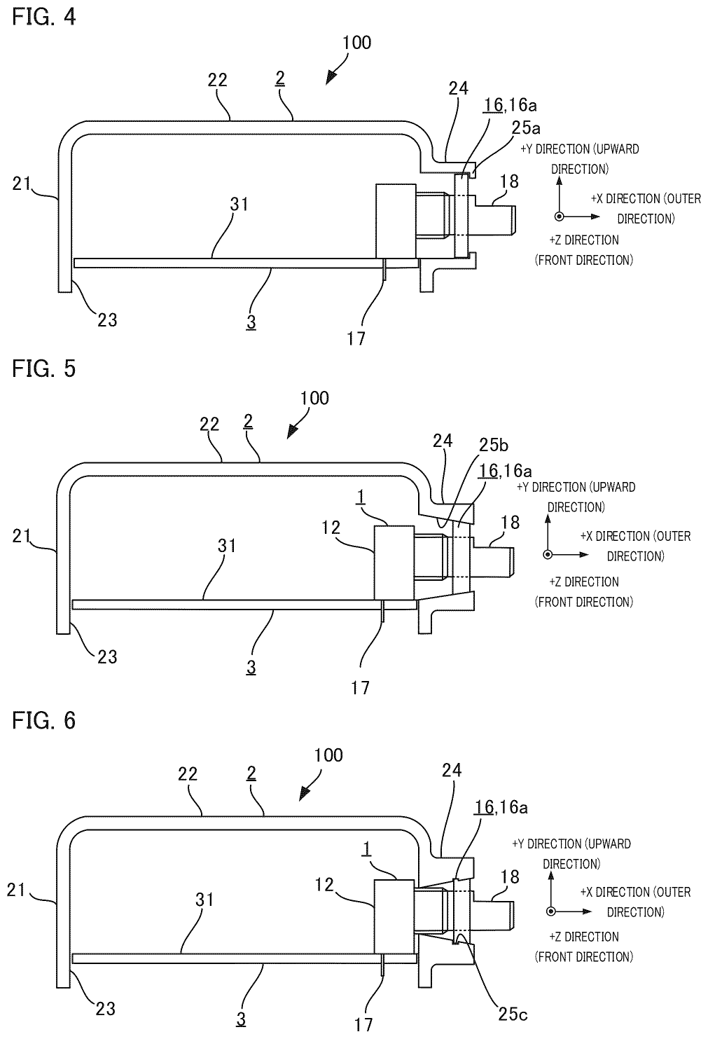

Next, a variation of electronic apparatus 100 in the present embodiment will be described with reference to FIG. 4. FIG. 4 illustrates electronic apparatus 100 in Variation 1. Note that, in the descriptions of the following variations, configurations different from those in the above embodiment will be mainly described, whereas the identical components are given the same reference numerals, and the descriptions thereof will be omitted.

In electronic apparatus 100 in the above embodiment, stopper 19 that prevents fitting member 16 from coming off is disposed on input shaft 18.

In contrast, in Variation 1, as illustrated in FIG. 4, stopper 25a that prevents fitting member 16 from coming off is disposed on cylindrical portion 24. Specifically, stopper 25a is disposed on an inner peripheral wall of cylindrical portion 24. The inner peripheral wall has a diameter on one side in the axial direction (+X direction) that is smaller than a diameter on the other side in the axial direction (−X direction). Thus, it is possible to prevent fitting member 16 externally fitting to input shaft 18 on the other side in the axial direction (−X direction) from coming off. Stopper 25a illustrated in FIG. 4 is disposed at an end of cylindrical portion 24 on the one side in the axial direction (+X direction).

### (Variation 2)

Next, electronic apparatus 100 in Variation 2 will be described. FIG. 5 illustrates electronic apparatus 100 in Variation 2. In Variation 2, as illustrated in FIG. 5, stopper 25b is configured by gradually decreasing a diameter of the inner peripheral wall of cylindrical portion 24 from the other side in the axial direction (−X direction) to the one side in the axial direction (+X direction). In other words, stopper 25b is configured by conically narrowing the inner peripheral wall from the other side in the axial direction (−X direction) to the one side in the axial direction (+X direction). Thus, it is possible to prevent fitting member 16 externally fitting to input shaft 18 on the other side in the axial direction (−X direction) from coming off. The outer periphery of fitting member 16 has a shape that corresponds to a conical shape of the inner peripheral wall.

### (Variation 3)

Next, electronic apparatus 100 in Variation 3 will be described. FIG. 6 illustrates electronic apparatus 100 in Variation 3. In Variation 3, as illustrated in FIG. 6, a diameter of the inner peripheral wall of cylindrical portion 24 gradually increases from the other side in the axial direction (−X direction) to the one side in the axial direction (+X direction). Stopper 25c is a concave groove disposed in an intermediate portion between the other side in the axial direction (−X direction) and the one side in the axial direction (+X direction) in the inner peripheral wall. Note that the outer periphery of fitting member 16 is formed in a convex shape corresponding to a shape of the concave groove of stopper 25c.

In the methods of assembling electronic apparatus 100 in the above embodiment and Variations 1 and 2, an external fitting of fitting member 16 to input shaft 18 is required before assembling case 2 and circuit board 3. In contrast, in Variation 3, the external fitting of fitting member 16 to input shaft 18 is possible even after case 2 and circuit board 3 are assembled. In addition, after electronic apparatus 100 is assembled, fitting member 16 is attachable to and detachable from input shaft 18 from the one side in the axial direction (+X direction). Thus, for example, it is possible to exchange deteriorated fitting member 16 for new fitting member 16.

The embodiment and variations described above are merely examples of specific implementation of the present invention, and the technical scope of the present invention should not be restrictively interpreted by these embodiments. That is, the present invention may be implemented in various forms without departing from the spirit thereof or the major features thereof.

This application is based on Japanese patent application No. 2022-071790, filed Apr. 25, 2022, the contents of which are incorporated herein by reference.

### INDUSTRIAL APPLICABILITY

The present invention is suitably used in an electronic apparatus including an electronic component, which is capable of sufficiently increasing a rotation torque, required to enhance waterproof property, and to easily solder a terminal to a circuit board.

### REFERENCE SIGNS LIST

1 Electronic component
2 Case
3 Circuit board
12 Electronic component main body
16 Fitting member
16a Annular portion
17 Terminal
18 Input shaft
19 Stopper
21 Peripheral wall
22 Ceiling wall
23 Opening portion
24 Cylindrical portion
25a, 25b, 25c Stopper
31 Surface
100 Electronic apparatus
200 Electronic apparatus
203 Circuit board
212 Electronic component main body
217 Terminal
218 Input shaft

1. An electronic component, comprising:
an electronic component main body disposed in an inside of a case and mounted on a surface in a circuit board, the surface facing the inside of the case;
an input shaft that that extends to an outside of the case from the electric component main body along the surface and through a cylindrical portion provided in the case; and
a fitting member that fits to a gap between the cylindrical portion and the input shaft.

2. The electronic component according to claim 1, wherein the fitting member includes an annular portion having an inner peripheral edge and an outer peripheral edge, the inner peripheral edge being in contact with an outer periphery of the input shaft, the outer peripheral edge being in contact with an inner periphery of the cylindrical portion.

3. The electronic component according to claim 2, wherein the annular portion is an elastic rubber ring.

4. The electronic component according to claim 1, wherein the input shaft includes a stopper that prevents the fitting member from coming off.

5. An electronic apparatus, comprising:
the electronic component according to claim 1;
the case; and
the circuit board.

6. The electronic apparatus according to claim 5, wherein the cylindrical portion includes a stopper that prevents the fitting member from coming off.

7. The electronic apparatus according to claim 6, wherein:
the stopper is disposed on an inner peripheral wall of the cylindrical portion, and
a diameter of the inner peripheral wall gradually decreases from an inner side of the case toward an outer side of the case.

8. The electronic apparatus according to claim 6, wherein:
the stopper is disposed on an inner peripheral wall of the cylindrical portion,
a diameter of the inner peripheral wall gradually increases from an inner side of the case toward an outer side of the case, and
the stopper is disposed in an intermediate portion between the outer side of the case and the inner side of the case on the inner peripheral wall.
